(19) United States
(12) Patent Application Publication
(10) Pub. No.: US 2026/0123189 A1
(43) Pub. Date: Apr. 30, 2026

(54) DISPLAY DEVICE

(71) Applicant: LG Display Co., Ltd., Seoul (KR)

(72) Inventors: Wonrae KIM, Paju-si (KR); Sunwoo KIM, Paju-si (KR); Kyungkook JANG, Paju-si (KR); Seonghan HWANG, Paju-si (KR); Byunggwan HYUN, Paju-si (KR)

(73) Assignee: LG Display Co., Ltd., Seoul (KR)

(21) Appl. No.: 19/368,358

(22) Filed: Oct. 24, 2025

(30) Foreign Application Priority Data
Oct. 30, 2024 (KR) 10-2024-0150458

(51) Int. Cl. H10K 59/122; H10K 59/80

(52) U.S. Cl. CPC H10K 59/122; H10K 59/8792

(57) ABSTRACT

A display device according to one or more examples includes a substrate, a display area including a plurality of sub-pixels, a non-display area outside the display area, a first electrode disposed in each of the plurality of sub-pixels on the substrate in the display area, and a bank disposed on the first electrode of the display area and located at a boundary between adjacent sub-pixels and overlapping a periphery of an upper surface of the first electrode, in which the bank includes a plurality of black-based particles having different diameters.

### CROSS-REFERENCE TO RELATED APPLICATIONS

The present application claims the benefit of and priority to Korean Patent Application No. 10-2024-0150458, filed Oct. 30, 2024, the entire contents of which are incorporated herein by reference for all purposes.

### BACKGROUND

### 1. Technical Field

The present disclosure relates to a display device.

### 2. Description of Related Art

As the information society develops, various demands for display devices for displaying images are increasing, and various types of display devices such as liquid crystal display (LCD) devices and organic light emitting diode (OLED) display devices are utilized.

A display device includes a plurality of pixels and a plurality of switching elements for driving and controlling the pixels.

The description of related art should not be considered prior art merely because it is mentioned in or associated with this section. The description of related art includes information that describes one or more aspects of the subject technology, and the description in this section does not limit the scope of the invention.

### SUMMARY

Embodiments of the present disclosure are directed to providing a display device in which it is possible to efficiently increase an optical density of a bank by arranging more particles in the same space.

Embodiments of the present disclosure are also directed to providing a display device with a high scattering rate in all of a red wavelength, a green wavelength, and a blue wavelength.

Embodiments of the present disclosure are also directed to providing a display device with improved external light reflection (or surface reflection).

Embodiments of the present disclosure are also directed to providing a display device with low reflection and low power.

Embodiments of the present disclosure are also directed to providing a display device which can have improved flexibility and can be applied to a foldable product in which a display area is folded.

Aspects of the present disclosure are not limited to the above-described aspects, and other technical aspects may be inferred from the following embodiments.

According to one embodiment, there is provided a display device including a substrate, a display area including a plurality of sub-pixels, a non-display area outside the display area, a first electrode disposed in each of the plurality of sub-pixels on the substrate in the display area, and a bank disposed on the first electrode of the display area and located at a boundary between adjacent sub-pixels and overlapping a periphery of an upper surface of the first electrode, in which the bank includes a plurality of black-based particles having different diameters.

According to another embodiment, there is provided a display device including a substrate, a display area and a non-display area outside the display area, a first electrode on the substrate in the display area, and a bank disposed on the first electrode in the display area and overlapping a periphery of an upper surface of the first electrode, in which the bank includes a plurality of black-based particles, and the plurality of black-based particles may have a plurality of diameters to generate a scattering rate with respect to red light, a scattering rate with respect to green light, and a scattering rate with respect to blue light at the same level.

Detailed matters of other embodiments are included in the detailed description and accompanying drawings.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further features, advantages, and aspects are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure.

FIG. 1 is a plan view of the display device according to one embodiment.

FIG. 2 is a cross-sectional view illustrating a bent state of the display panel according to FIG. 1.

FIG. 3 is a cross-sectional view along line A-A′ in FIG. 1.

FIG. 4 is a specific cross-sectional view of a light-emitting part of FIG. 3.

FIG. 5 is a specific cross-sectional view of a light-emitting part according to a modified example.

FIG. 6 is a cross-sectional view of a touch part according to FIG. 3.

FIG. 7 is an enlarged cross-sectional view of area Q1 in FIG. 3.

FIG. 8 is a view illustrating the scattering tendency of particles with different diameters with respect to light.

FIG. 9 is a graph illustrating a scattering rate according to the wavelength of particles with different diameters.

FIG. 10 is a view illustrating the scattering of a first particle, a second particle, and a third particle with respect to light of different wavelengths.

FIG. 11 is a cross-sectional view of a display device according to another embodiment.

FIG. 12 is a cross-sectional view of a display device according to still another embodiment.

FIG. 13 is a perspective view of a display device according to yet another embodiment.

FIG. 14 is a cross-sectional view along line B-B′ in FIG. 13.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Hereinafter, embodiments will be described with reference to the accompanying drawings.

The same reference numerals indicate the same components. In addition, in the drawings, thicknesses, proportions, and dimensions of components can be exaggerated for effective description of technical contents. Scales of components illustrated in the drawings differ from the actual scale for convenience of description, and thus are not limited to the scales illustrated in the drawings.

In the present disclosure, when a first component (or an area, a layer, a portion, etc.) is described as “on,” “connected,” or “coupled to” a second component, it means that the first component may be directly connected/coupled to the second component or a third component may be disposed therebetween.

The term “and/or” includes all one or more combinations that may be defined by the associated configurations.

Terms such as first and second may be used to describe various components, but the components are not limited by the terms. The terms are used only for the purpose of distinguishing one component from another. For example, a first component may be referred to as a second component, and similarly, the second component may also be referred to as the first component without departing from the scopes of the embodiments. The singular includes the plural unless the context clearly dictates otherwise. For example, an element may be one or more elements. An element may include a plurality of elements.

Terms such as “under,” “at a lower side,” “above,” and “at an upper side” are used to describe the relationship between the components illustrated in the drawings. The terms are relative concepts and are described with respect to directions marked in the drawings. For example, as long as “immediately” or “directly” is not used, one or more other portions may be positioned between two portions. The spatially relative terms “below or beneath,” “lower,” “above,” “upper,” etc. can be used to easily describe the correlation with one element or components and another element or components as shown in the drawings. The spatially relative terms should be understood as the terms including different directions of elements in use or operation in addition to the directions shown in the drawings. For example, in case of turning the element shown in the drawing upside down, an element described as being disposed “below” or “beneath” another element may be disposed “above” another element. Accordingly, the exemplary term “below” may include both downward and upward directions.

When the term “comprise,” “have,” “include,” “contain,” “constitute,” “made of,” “formed of,” “composed of,” or the like is used with respect to one or more elements (e.g., layers, films, components, electrodes, structures, transistors, sections, members, parts, regions, areas, portions, features, numbers, steps, operations, and/or the like), one or more other elements may be added unless a term such as “only” or the like is used. The terms used in the present disclosure are merely used in order to describe particular example embodiments, and are not intended to limit the scope of the present disclosure. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

Features of various embodiments of the present disclosure may be coupled or combined partially or entirely, various technological interworking and driving are made possible, and the embodiments may be implemented independently of each other or implemented together in an associated relationship.

Hereinafter, a display device of the present disclosure will be described with reference to the accompanying drawings and embodiments as follows.

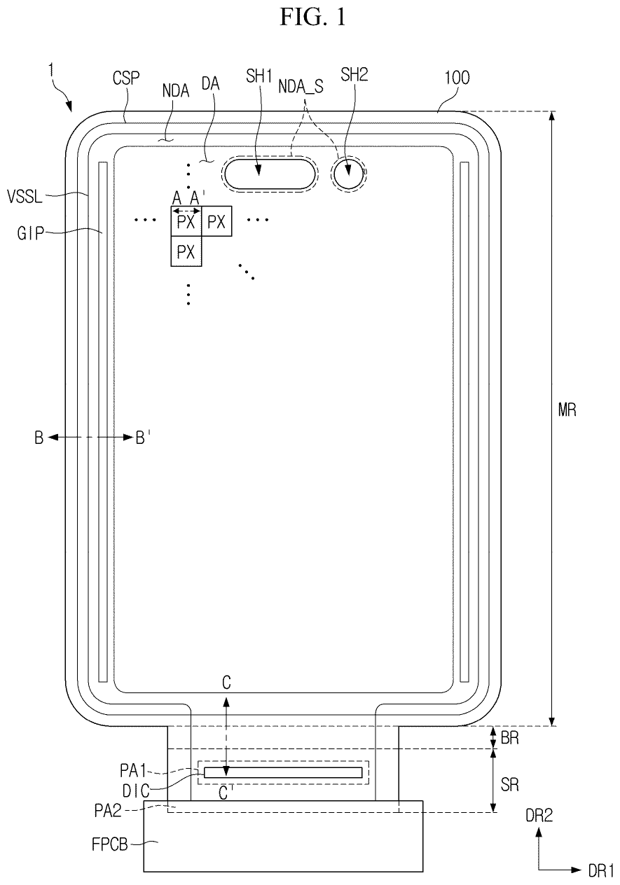

FIG. 1 is a plan view of the display device according to one embodiment.

Referring to FIG. 1, a display device 1 according to one embodiment may include a display panel 100. The display panel 100 may include a display area DA including a plurality of pixels PX and a non-display area NDA around the display area DA. The flat surface shape of the display area DA may have a rectangular shape. However, the embodiments of the present disclosure are not limited thereto, and the flat surface shape of the display area DA may be a square, circular, elliptical, or other polygonal shapes. For example, the display area DA may have a rectangular shape with rounded corners, but is not limited thereto and may also have a rectangular shape with angled corners.

In embodiments, a first direction DR1 and a second direction DR2 are different directions and intersect each other, for example, directions that intersect vertically in a plan view. In FIG. 1, the first direction DR1 may be generally the same as an extension direction of short sides of the display panel 100, and the second direction DR2 may be the same as an extension direction of long sides of the display panel 100. However, the directions described in the embodiments should be understood as indicating relative directions, and the embodiments are not limited to the described directions.

The display area DA may include short sides extending in the first direction DR1 and long sides extending in the second direction DR2. The non-display area NDA may surround the display area DA. The non-display area NDA may be disposed at one side and the other side of the display area DA in the first direction DR1 and one side and the other side of the display area DA in the second direction DR2.

The display panel 100 may further include a sensor non-display area NDA_S and a sensor hole SH1, SH2 surrounded by the sensor non-display area NDA_S. The sensor hole SH1 and SH2 may be surrounded by the display area DA in a plan view. The sensor hole SH1 and SH2 may be, for example, two sensor holes as in FIG. 1, but the embodiments of the present disclosure are not limited thereto. For example, the sensor hole may be provided as one sensor hole. The two sensor holes SH1 and SH2 may each include a sensor hole in which an infrared sensor is disposed and a sensor hole in which a camera sensor is disposed, but the embodiments of the present disclosure are not limited thereto. The sensor non-display area NDA_S may be disposed between the sensor holes SH1 and SH2 and the display area DA. The sensor non-display area NDA_S may completely surround the sensor holes SH1 and SH2. A pixel PX may not be disposed in the sensor non-display area NDA_S.

A gate driving unit GIP may be disposed in the non-display area NDA located at one side and the other side of the display area DA in the first direction DR1. A low-potential voltage line VSSL may be disposed outside the gate driving unit GIP on the non-display area NDA. For example, as illustrated in FIG. 1, the low-potential voltage line VSSL may extend from a printed circuit board FPCB, pass a sub-region SR and a bending region BR, may be located outside the gate driving unit GIP on the non-display area NDA, and disposed to surround the display area DA.

The non-display area NDA located at the other side of the display area DA in the second direction DR2 may extend further from a central portion of the other side toward the other side of the display area DA in the second direction DR2. A width of the non-display area NDA in the first direction DR1 further extending from the central portion of the other side toward the other side of the display area DA in the second direction DR2 may be smaller than a width of the non-display area NDA in the first direction DR1 adjacent to the other side of the display area DA in the second direction DR2.

The display device 1 may include a main region MR, the sub-region SR, and the bending region BR between the main region MR and the sub-region SR. The display area DA and the non-display area NDA surrounding four surfaces of the display area DA may form the main region MR, and a portion further extending from the central portion of the other side toward the other side of the display area DA in the second direction DR2 may form the bending region BR and the sub-region SR. The bending region BR may be disposed between the sub-region SR and the main region MR. The sub-region SR may include a first pad area PA1 and a second pad area PA2 located at an end portion of the other side of the sub-region SR in the second direction DR2. The display device 1 may further include a data driving unit DIC and a printed circuit board FPCB. The data driving unit DIC may be disposed in the first pad area PA1, and the printed circuit board FPCB may be attached to the second pad area PA2. A plurality of pads connected to the data driver DIC and the printed circuit board FPCB may be disposed in each of the first pad area PA1 and the second pad area PA2. The data driving unit DIC may be configured, for example, in the form of a driving chip (IC), but is not limited thereto. In one embodiment, a case in which the data driving unit DIC is disposed by a chip on plastic method in which the data driving unit DIC is directly mounted on the display panel 100 is described, but the embodiments of the present disclosure are not limited thereto, and the data driving unit DIC may be disposed by a chip on glass or chip on film method.

The display panel 100 according to one embodiment may further include a crack sensing pattern CSP surrounding the low-potential voltage line VSSL. The crack sensing pattern CSP may be disposed to completely surround the display area DA as illustrated in FIG. 1. For example, the crack sensing pattern CSP may be disposed outside the low-potential voltage line VSSL. However, the embodiments of the present disclosure are not limited thereto, and a part of the crack sensing pattern CSP may not be disposed in the non-display area NDA of the other side of the display area DA in the second direction DR2.

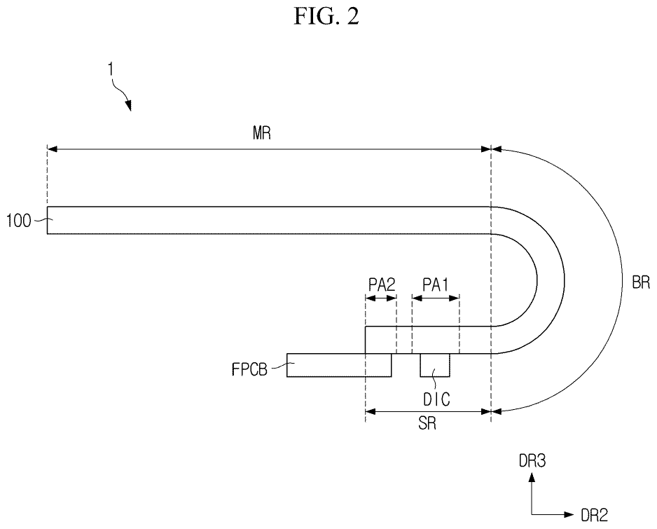

FIG. 2 is a cross-sectional view illustrating a bent state of the display panel according to FIG. 1.

Referring to FIG. 2, the bending region BR of the display panel 100 of the display device 1 according to one embodiment may be bent in a thickness direction (or a third direction DR3). Accordingly, the main region MR and the sub-region SR may overlap each other in the thickness direction. The display panel 100 may be bent in such a manner that a lower surface of the main region MR faces an upper surface of the sub-region SR. The printed circuit board FPCB may be attached to an end portion of the sub-region SR.

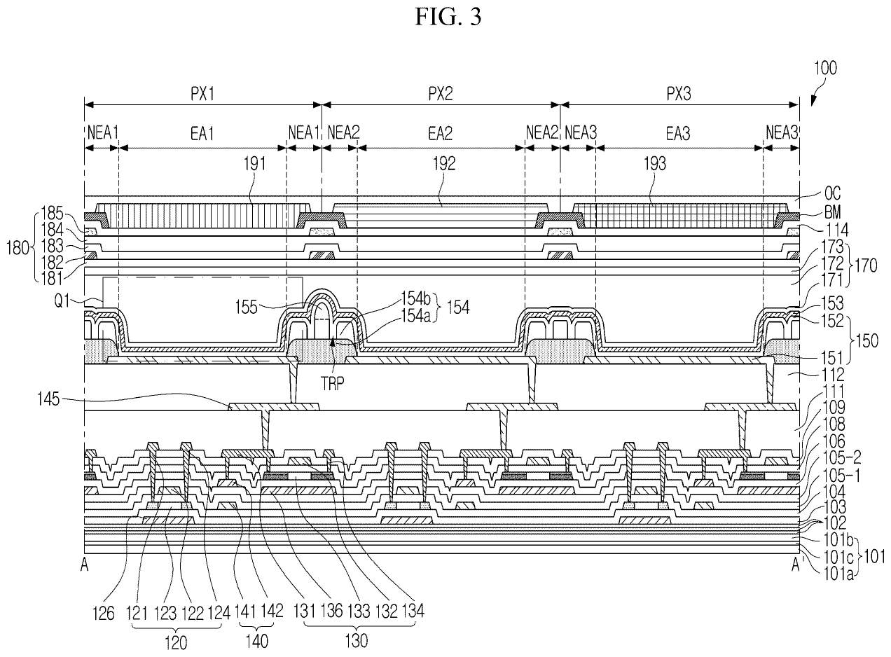

FIG. 3 is a cross-sectional view along line A-A′ in FIG. 1.

Referring to FIG. 3, the pixel PX (see FIG. 1) of the display panel 100 may include a plurality of sub-pixels PX1, PX2, and PX3. A first sub-pixel PX1 may be a red sub-pixel, a second sub-pixel PX2 may be a green sub-pixel, and a third sub pixel PX3 may be a blue sub-pixel, but the embodiments of the present disclosure are not limited thereto. In some embodiments, the pixel PX further includes a fourth sub-pixel, and the fourth sub-pixel may be a white sub-pixel, but the embodiments of the present disclosure are not limited thereto. In some embodiments, the pixel may include one red sub-pixel, two green sub-pixels, and one blue sub-pixel, but the embodiments of the present disclosure are not limited thereto. For example, the plurality of sub-pixels PX1, PX2, and PX3 may be arranged in a stripe manner in the first direction DR1, but are not limited thereto, and may be arranged in a pentile manner.

The display panel 100 may include a substrate 101, a first thin film transistor 120, a second thin film transistor 130, a light-emitting part 150, an encapsulation part 170, a touch part 180, a filter insulating layer 114, a black matrix BM, color filters 191, 192, and 193, and a planarization layer OC. The display panel 100 may include at least one panel insulating layer and at least one touch insulating layer between the substrate 101 and the light-emitting part 150. The at least one panel insulating layer may include at least one of a buffer layer 102, a first insulating layer 103, a second insulating layer 104, a 3-1 insulating layer 105-1, a 3-2 insulating layer 105-2, a fourth insulating layer 106, a fifth insulating layer 108, a sixth insulating layer 109, a first protective layer 111, and a second protective layer 112, and the at least one touch insulating layer may include at least one of a touch buffer layer 181, a first touch insulating layer 183, and a second touch insulating layer 184.

The substrate 101 may include one or more plastic materials. For example, the substrate 101 may be a multi-substrate including a plurality of plastic materials, such as polyimide, etc. For example, the substrate 101 may include a first substrate portion 101a and a second substrate portion 101b each including a plastic material, and a third substrate portion 101c including an inorganic insulation material between the first substrate portion 101a and the second substrate portion 101b, but the embodiments of the present disclosure are not limited thereto. The substrate 101 may be a flexible substrate.

The buffer layer 102 may be disposed on the substrate 101. The buffer layer 102 can minimize or delay the diffusion of moisture or oxygen penetrating the substrate 101. The buffer layer 102 may be formed by alternately stacking silicon nitride (SiNₓ) and silicon oxide (SiOₓ) at least once, but the embodiments of the present disclosure are not limited thereto.

A first light-blocking layer 126 may be disposed on the buffer layer 102. The first light-blocking layer 126 can prevent light from transmitting a first semiconductor layer 123 of the first thin film transistor 120. For example, the first semiconductor layer 123 may be disposed to overlap the first light-blocking layer 126. The first light-blocking layer 126 may be formed of a single layer or multiple layers formed of one of molybdenum (Mo), aluminum (Al), chromium (Cr), nickel (Ni), neodymium (Nd), and copper (Cu) or an alloy thereof, but the embodiments of the present disclosure are not limited thereto.

The first insulating layer 103 may be disposed on the buffer layer 102 and the first light-blocking layer 126. The first insulating layer 103 can prevent a short circuit between a component of the first thin film transistor 120 and the first light-blocking layer 126. The first insulating layer 103 may be formed of the same material as the buffer layer 102, but the embodiments of the present disclosure are not limited thereto. For example, the first insulating layer 103 may be formed of an inorganic insulation material, such as silicon nitride (SiNₓ) or silicon oxide (SiOₓ), but the embodiments of the present disclosure are not limited thereto.

The first thin film transistor 120 may be disposed on the first insulating layer 103. The first thin film transistor 120 may include a first source electrode 121, a first gate electrode 122, the first semiconductor layer 123, and a first drain electrode 124.

The first semiconductor layer 123 may be disposed on the first insulating layer 103. The first semiconductor layer 123 may include a metal oxide semiconductor, such as indium-gallium-zinc oxide (IGZO), and a silicon-based semiconductor material, such as amorphous silicon, polycrystalline silicon, etc., but the embodiments of the present disclosure are not limited thereto. The first semiconductor layer 123 may include a channel area, a source area, and a drain area.

Since the polycrystalline semiconductor layer has higher mobility than the amorphous semiconductor layer and the oxide semiconductor layer, power consumption can be less, and reliability can be excellent. Accordingly, a driving transistor may be formed of the polycrystalline semiconductor layer.

The second insulating layer 104 may be disposed on the first semiconductor layer 123. The second insulating layer 104 may be formed of the same material as the first insulating layer 103 and can prevent a short circuit between the first semiconductor layer 123 and another component of the first thin film transistor 120.

The first gate electrode 122 may be disposed on the second insulating layer 104. The first gate electrode 122 may be disposed on the second insulating layer 104 to overlap the channel area of the first semiconductor layer 123. The first gate electrode 122 may be formed of a single layer or multiple layers formed of molybdenum (Mo), copper (Cu), titanium (Ti), aluminum (Al), chromium (Cr), gold (Au), nickel (Ni), neodymium (Nd), or a compound thereof, but the embodiments of the present disclosure are not limited thereto. The first gate electrode 122 may be disposed along with a gate line.

Third insulating layers 105-1 and 105-2 may be disposed on the first gate electrode 122. The third insulating layers 105-1 and 105-2 may be formed by alternately stacking silicon nitride (SiNₓ) and silicon oxide (SiOₓ) at least once, but the embodiments of the present disclosure are not limited thereto. For example, a 3-1 insulating layer 105-1 may include silicon oxide (SiOₓ), and a 3-2 insulating layer 105-2 may include silicon nitride (SiNₓ), but the embodiments of the present disclosure are not limited thereto.

The first source electrode 121 and the first drain electrode 124 may be disposed on the third insulating layers 105-1 and 105-2.

The first source electrode 121 and the first drain electrode 124 may be electrically connected to the first semiconductor layer 123 through contact holes. The first source electrode 121 and the first drain electrode 124 may be formed of a metallic material. For example, the first source electrode 121 and the first drain electrode 124 may be formed of a single layer or multiple layers formed of one of molybdenum (Mo), aluminum (Al), chromium (Cr), gold (Au), titanium (Ti), nickel (Ni), neodymium (Nd), and copper (Cu) or an alloy thereof, but the embodiments of the present disclosure are not limited thereto.

The first source electrode 121 and the first drain electrode 124 may be disposed along with a data line. For example, the data line may be formed of the same material as the first source electrode 121 and the first drain electrode 124 and formed on the same layer as the first source electrode 121 and the first drain electrode 124, but the embodiments of the present disclosure are not limited thereto.

A storage electrode 140 may be disposed to be spaced apart from the first thin film transistor 120. The storage electrode 140 may include a first storage electrode 141 and a second storage electrode 142.

The first storage electrode 141 may be formed of the same material as the first gate electrode 122 and disposed on the same layer as the first gate electrode 122, but the embodiments of the present disclosure are not limited thereto.

The second storage electrode 142 may be disposed on the first storage electrode 141. The second storage electrode 142 may be disposed on the third insulating layers 105-1 and 105-2, and the third insulating layers 105-1 and 105-2 between the first storage electrode 141 and the second storage electrode 142 may be used as a dielectric to generate a capacitance. The second storage electrode 142 may be formed of the same material as the first storage electrode 141, but the embodiments of the present disclosure are not limited thereto.

The second thin film transistor 130 may be disposed to be spaced apart from the first thin film transistor 120 and the storage electrode 140. The second thin film transistor 130 may include a second source electrode 131, a second gate electrode 132, a second semiconductor layer 133, and a second drain electrode 134.

A second light-blocking layer 136 may be disposed on the same layer as the second storage electrode 142.

The second light-blocking layer 136 can prevent light from traveling to the second semiconductor layer 133 similar to the first light-blocking layer 126, thereby extending the life of the second thin film transistor 130. For example, the second semiconductor layer 133 may be disposed to overlap the second light-blocking layer 136.

A fourth insulating layer 106 may be disposed on the second light-blocking layer 136. The fourth insulating layer 106 may be formed of the same material as the first insulating layer 103, the second insulating layer 104, or the third insulating layers 105-1 and 105-2, but the embodiments of the present disclosure are not limited thereto.

The second semiconductor layer 133 may be disposed on the fourth insulating layer 106. The second semiconductor layer 133 may include a source area, a drain area, and a channel area between the source area and the drain area.

The second semiconductor layer 133 may include a metal oxide semiconductor, such as indium-gallium-zinc oxide (IGZO), and a silicon-based semiconductor material, such as amorphous silicon, polycrystalline silicon, etc., but the embodiments of the present disclosure are not limited thereto.

A fifth insulating layer 108 may be disposed on the second semiconductor layer 133. The fifth insulating layer 108 may be formed of the same material as the first insulating layer 103, the second insulating layer 104, the third insulating layers 105-1 and 105-2, or the fourth insulating layer 106, but the embodiments of the present disclosure are not limited thereto.

The second gate electrode 132 may be disposed on the fifth insulating layer 108.

The second gate electrode 132 may be formed of the same material as the first gate electrode 122. For example, the second gate electrode 132 may be formed of a single layer or multiple layers formed of molybdenum (Mo), copper (Cu), titanium (Ti), aluminum (Al), chromium (Cr), gold (Au), nickel (Ni), neodymium (Nd), or a compound thereof, but the embodiments of the present disclosure are not limited thereto.

A sixth insulating layer 109 may be disposed on the second gate electrode 132. The sixth insulating layer 109 may be formed of the same material as the first insulating layer 103, the second insulating layer 104, the third insulating layers 105-1 and 105-2, the fourth insulating layer 106, or the fifth insulating layer 108, but the embodiments of the present disclosure are not limited thereto.

The first source electrode 121, the first drain electrode 124, the second source electrode 131, and the second drain electrode 134 may be disposed on the sixth insulating layer 109.

The second source electrode 131 and the second drain electrode 134 may be formed of the same material as the first source electrode 121 and the first drain electrode 124 and disposed on the same layer as the first source electrode 121 and the first drain electrode 124, but the embodiments of the present disclosure are not limited thereto. For example, the second source electrode 131 and the second drain electrode 134 may be formed of a single layer or multiple layers formed of any one of molybdenum (Mo), aluminum (Al), chromium (Cr), gold (Au), titanium (Ti), nickel (Ni), neodymium (Nd), and copper (Cu) or an alloy thereof, but the embodiments of the present disclosure are not limited thereto. For example, the second source electrode 131 may be electrically connected to the second storage electrode 142. The second source electrode 131 may pass through the sixth insulating layer 109, the fifth insulating layer 108, and the fourth insulating layer 106 and may be electrically connected to the second storage electrode 142.

The first thin film transistor 120 may be a driving transistor, and the second thin film transistor 130 may be a switching transistor, but the embodiments of the present disclosure are not limited thereto.

A first protective layer 111 may be disposed on the first source electrode 121 and the first drain electrode 124.

The first protective layer 111 may planarize an upper portion of the first thin film transistor 120 and protect the first thin film transistor 120. The first protective layer 111 may be formed of an organic material. For example, the first protective layer 111 may be formed of an organic material including an acrylic resin, an epoxy resin, a phenolic resin, a polyamide resin, or a polyimide resin, but the embodiments of the present disclosure are not limited thereto.

The second protective layer 112 may be disposed on the first protective layer 111. The second protective layer 112 may be formed of the same material as the first protective layer 111, but the embodiments of the present disclosure are not limited thereto.

In some embodiments, a third protective layer may be further disposed on an upper surface of the second protective layer 112, but the embodiments of the present disclosure are not limited thereto.

A connection electrode 145 may be disposed between the first protective layer 111 and the second protective layer 112.

The connection electrode 145 may electrically connect the first thin film transistor 120 to the light-emitting part 150. The connection electrode 145 may be formed of the same material as the first source electrode 121 and the first drain electrode 124, but the embodiments of the present disclosure are not limited thereto.

The connection electrode 145 may be formed of a single layer or multiple layers formed of one of molybdenum (Mo), aluminum (Al), chromium (Cr), gold (Au), titanium (Ti), nickel (Ni), neodymium (Nd), and copper (Cu) or an alloy thereof, but the embodiments of the present disclosure are not limited thereto.

The light-emitting part 150 may be disposed on the second protective layer 112. The light-emitting part 150 may include a first electrode 151, an organic layer 152, and a second electrode 153. The first electrode 151 may serve as an anode, and the second electrode 153 may serve as a cathode.

The first electrode 151 may be disposed on the second protective layer 112. The first electrode 151 may be electrically connected to the first thin film transistor 120 through a contact hole formed in the second protective layer 112. The first electrode 151 may be a reflective electrode that reflects light, but the embodiments of the present disclosure are not limited thereto. The first electrode 151 may include a metallic material with high reflectance, such as a stacking structure (Ti/Al/Ti) of aluminum (Al) and titanium (Ti), a stacking structure (ITO/Al/ITO) of aluminum (Al) and indium tin oxide (ITO), or an APC alloy and may be formed of a single layer or multiple layers, but the embodiments of the present disclosure are not limited thereto.

The organic layer 152 may be disposed on the first electrode 151. The organic layer 152 may include one or more light-emitting structures (or light-emitting elements or elements) stacked on the first electrode 151 in the order or reverse order of a hole transfer layer and an electron transfer layer. For example, the hole transfer layer may include a hole transporting layer, a hole injecting layer, an electron blocking layer, a p-type charge generation layer, etc., but the embodiments of the present disclosure are not limited thereto. For example, the electron transfer layer may include an electron transporting layer, an electron injecting layer, a hole blocking layer, an n-type charge generation layer, etc., but the embodiments of the present disclosure are not limited thereto. The organic layer 152 may be an organic light-emitting layer, an inorganic light-emitting layer, a quantum dot light-emitting layer, a micro light-emitting diode, a micro mini light-emitting diode, etc., but the embodiments of the present disclosure area not limited thereto. For example, the organic layer 152 of the display panel 100 according to one embodiment of the present disclosure may include an organic light-emitting layer. The organic layer 152 may include a red light-emitting layer, a green light-emitting layer, and a blue light-emitting layer. The organic layer 152 may be a white light-emitting layer, but the embodiments of the present disclosure are not limited thereto. Hereinafter, a specific structure of the organic layer 152 according to one embodiment will be described.

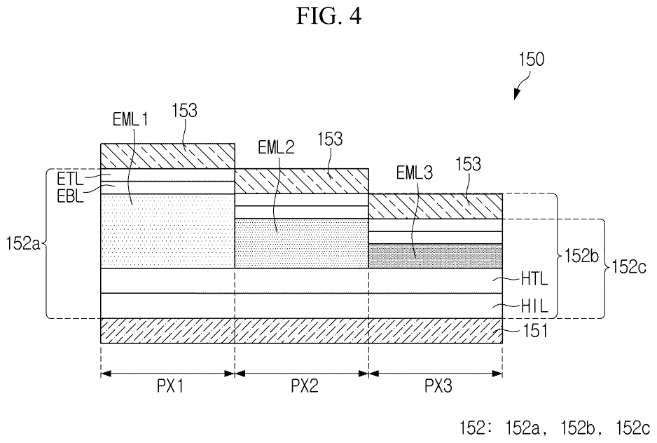

FIG. 4 is a specific cross-sectional view of a light-emitting part of FIG. 3.

Referring to FIG. 4, the light-emitting part 150 may include the first sub-pixel PX1, the second sub-pixel PX2, and the third sub-pixel PX3.

A thickness of the light-emitting part 150 in each sub-pixel PX1, PX2, or PX3 may be different, but the embodiments of the present disclosure are not limited thereto, and the thickness of the light-emitting part 150 in each sub-pixel PX1, PX2, or PX3 may be the same.

The organic layer 152 may include a first organic layer 152a disposed in the first sub-pixel PX1, a second organic layer 152b disposed in the second sub-pixel PX2, and a third organic layer 152c disposed in the third sub-pixel PX3. The light-emitting layers EML1, EML2, and EML3 of the organic layers 152a, 152b, and 152c may be physically separated, but lower layers and upper layers of the light-emitting layers EML1, EML2, and EML3 may be formed integrally across the sub-pixels PX1, PX2, and PX3. A thicknesses of each light-emitting layer EML1, EML2, or EML3 may be different. For example, a thickness of a first light-emitting layer EML1 may be the greatest, a thickness of a second light-emitting layer EML2 may be the second greatest, and a thickness of the third light-emitting layer EML3 may be the smallest, but the embodiments of the present disclosure are not limited thereto.

A hole injecting layer HIL may be disposed on the first electrode 151. The hole injecting layer HIL may be located between the first electrode 151 and the light-emitting layers EML1, EML2, and EML3. The hole injecting layer HIL may be formed integrally across the sub-pixels PX1, PX2, and PX3. For example, the hole injecting layer HIL may be formed of a hole injecting material that is one selected from MTDATA, CuPc, TCTA, NPB (NPD), HATCN, TDAPB, PEDOT/PSS, F4TCNQ, N-(biphenyl-4-yl)-9,9-dimethyl-N-(4-(9-phenyl-9H-carbazol-3-yl)phenyl)-9H-fluoren-2-amine, etc., but the embodiments of the present disclosure are not limited thereto.

A hole transporting layer HTL may be disposed on the hole injecting layer HIL. The hole transporting layer HTL may be located between the hole injecting layer HIL and the light-emitting layers EML1, EML2, and EML3. The hole transporting layer HTL may be formed integrally across the sub-pixels PX1, PX2, and PX3. The hole transporting layer HTL may be formed of one or more selected from the group consisting of arylamine-based materials, such as NPB (N,N-naphthyl-N,N′-phenyl benzidine), TPD (N,N′-bis-(3-methylphenyl)-N,N′-bis-(phenyl)-benzidine), PPD, TTBND, FFD, p-dmDPS, and TAPC, starbust aromatic amine-based materials, such as TCTA, PTDATA, TDAPB, TDBA, 4-a, and TCTA, and spiro and ladder type materials, such as Spiro-TPD, Spiro-mTTB, and Spiro-2, NPD (N, N-dinaphthylN,N′-diphenyl benzidine), s-TAD, and MTDATA(4,4′,4″-Tris(N-3-methylphenyl-N-phenyl-amino)-triphenylamine), but the embodiments of the present disclosure are not limited thereto.

The light-emitting layers EML1, EML2, and EML3 may be disposed on the hole transporting layer HTL. The first light-emitting layer EML1 may be disposed in the first sub-pixel PX1, the second light-emitting layer EML2 may be disposed in the second sub-pixel PX2, and the third light-emitting layer EML3 may be disposed in the third sub-pixel PX3.

A thicknesses of each light-emitting layer EML1, EML2, or EML3 may be different. For example, the first light-emitting layer EML1 may be formed in a thickness of 60 to 80 nm, the second light-emitting layer EML2 may be formed in a thickness of 30 to 50 nm, and the third light-emitting layer EML3 may be formed in a thickness of 10 to 30 nm, but the embodiments of the present disclosure are not limited thereto.

Each of the first light-emitting layer EML1, the second light-emitting layer EML2, and the third light-emitting layer EML3 may include a material that may emit light in the visible light range by receiving and combining holes and electrons.

An electron blocking layer EBL may be disposed on each light-emitting layer EML1, EML2, or EML3. The electron blocking layer EBL may be disposed integrally across the sub-pixels PX1, PX2, and PX3.

An electron transporting layer ETL may be disposed on the electron blocking layer EBL. The electron transporting layer ETL may be disposed integrally across the sub-pixels PX1, PX2, and PX3. The electron transporting layer ETL may be formed of an anthracene derivative and lithium quinolate (Liq) or formed of one or more selected from oxadiazole, triazole, phenanthroline, benzoxazole, benzthiazole, or benzimidazole (e.g., 2-[4-(9,10-Di-2-naphthalenyl-2-anthracenyl)phenyl]-1-phenyl-1H-benzimidazole), but the embodiments of the present disclosure are not limited thereto.

The second electrode 153 may be disposed on the electron transporting layer ETL.

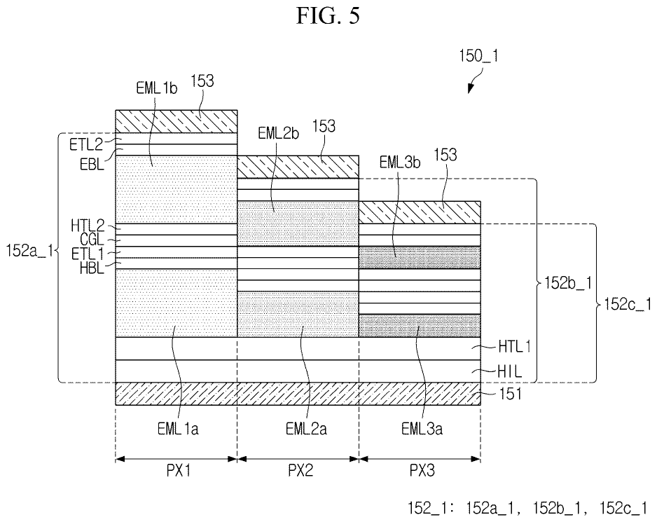

FIG. 5 is a specific cross-sectional view of a light-emitting part according to a modified example.

Referring to FIGS. 4 and 5, an organic layer 152_1 may include a first organic layer 152a_1 disposed in the first sub-pixel PX1, a second organic layer 152b_1 disposed in the second sub-pixel PX2, and a third organic layer 152c_1 disposed in the third sub-pixel PX3. In the present disclosure, as illustrated in FIGS. 4 and 5, an example in which the light-emitting layer is formed in one stack or two stacks for each sub-pixel PX1, PX2, or PX3 of the organic layers 152 and 152_1 is illustrated, but the embodiments of the present disclosure are not limited thereto, and the light-emitting layer may be formed in three or more stacks.

The light-emitting layers of each organic layer 152a_1, 152b_1, or 152c_1 may be physically separated, but the lower layers and upper layers of the light-emitting layers may be formed integrally across the sub-pixels PX1, PX2, and PX3. The thickness of each light-emitting layer may be different. For example, the thickness of the first light-emitting layer of the first sub-pixel may be the greatest, the thickness of the second light-emitting layer of the second sub-pixel may be the second greatest, and the thickness of the third light-emitting layer of the third sub-pixel may be the smallest, but the embodiments of the present disclosure are not limited thereto. In addition, the light-emitting layers of each organic layer 152a_1, 152b_1, or 152c_1 may be provided as two or more light-emitting layers.

A hole injecting layer HIL may be disposed on the first electrode 151. The hole injecting layer HIL may be located between the first electrode 151 and the light-emitting layers EML1a, EML2a, and EML3a. The hole injecting layer HIL may be formed integrally across the sub-pixels PX1, PX2, and PX3. For example, the hole injecting layer HIL may be formed of a hole injecting material that is one selected from MTDATA, CuPc, TCTA, NPB (NPD), HATCN, TDAPB, PEDOT/PSS, F4TCNQ, N-(biphenyl-4-yl)-9,9-dimethyl-N-(4-(9-phenyl-9H-carbazol-3-yl)phenyl)-9H-fluoren-2-amine, etc., but the embodiments of the present disclosure are not limited thereto.

A first hole transporting layer HTL1 may be disposed on the hole injecting layer HIL. The first hole transporting layer HTL1 may be located between the hole injecting layer HIL and light-emitting layers EML1a, EML2a, and EML3a. The first hole transporting layer HTL1 may be formed integrally across the sub-pixels PX1, PX2, and PX3. The first hole transporting layer HTL1 may be formed of one or more selected from the group consisting of arylamine-based materials, such as NPB (N,N-naphthyl-N,N′-phenyl benzidine), TPD (N,N′-bis-(3-methylphenyl)-N, N′-bis-(phenyl)-benzidine), PPD, TTBND, FFD, p-dmDPS, and TAPC, starbust aromatic amine-based materials, such as TCTA, PTDATA, TDAPB, TDBA, 4-a, and TCTA, and spiro and ladder type materials, such as Spiro-TPD, Spiro-mTTB, and Spiro-2, NPD (N,N-dinaphthylN,N′-diphenyl benzidine), s-TAD, and MTDATA(4,4′,4″-Tris(N-3-methylphenyl-N-phenyl-amino)-triphenylamine), but the embodiments of the present disclosure are not limited thereto.

The light-emitting layers EML1a, EML2a, and EML3a may be disposed on the first hole transporting layer HTL1. A 1-1 light-emitting layer EML1a may be disposed in the first sub-pixel PX1, a 2-1 light-emitting layer EML2a may be disposed in the second sub-pixel PX2, and a 3-1 light-emitting layer EML3a may be disposed in the third sub-pixel PX3. Each of the light-emitting layers EML1a, EML2a, and EML3a of FIG. 5 may be the same as each of the light-emitting layers EML1, EML2, and EML3 of FIG. 4.

A thicknesses of each light-emitting layer EML1a, EML2a, or EML3a may be different. For example, the 1-1 light-emitting layer EML1a may be formed in a thickness of 60 to 80 nm the 2-1 light-emitting layer EML2a may be formed in a thickness of 30 to 50 nm, and the 3-1 light-emitting layer EML3a may be formed in a thickness of 10 to 30 nm, but the embodiments of the present disclosure are not limited thereto.

A hole blocking layer HBL may be disposed on each light-emitting layer EML1a, EML2a, or EML3a. The hole blocking layer HBL may be disposed integrally across the sub-pixels PX1, PX2, and PX3.

A first hole transporting layer ETL1 may be disposed on the hole blocking layer HBL. The first electron transporting layer ETL1 may be formed integrally across the sub-pixels PX1, PX2, and PX3. The first electron transporting layer ETL1 may be formed of an anthracene derivative and lithium quinolate (Liq) or formed of one or more selected from oxadiazole, triazole, phenanthroline, benzoxazole, benzthiazole, or benzimidazole (e.g., 2-[4-(9,10-Di-2-naphthalenyl-2-anthracenyl)phenyl]-1-phenyl-1H-benzimidazole), but the embodiments of the present disclosure are not limited thereto.

A common charge layer CGL may be disposed on the first electron transporting layer ETL1. The common charge layer CGL may be disposed between the first electron transporting layer ETL1 and the second hole transporting layer HTL2. The common charge layer CGL may include a conductive material, but the embodiments of the present disclosure are not limited thereto.

The second hole transporting layer HTL2 may be disposed on the common charge layer CGL. The second hole transporting layer HTL2 may be disposed between the hole blocking layer HBL and the light-emitting layers EML1b, EML2b, and EML3b. The second hole transporting layer HTL2 may be formed integrally across the sub-pixels PX1, PX2, and PX3. A material of the second hole transporting layer HTL2 may be the same as a material of the first hole transporting layer HTL1, but the embodiments of the present disclosure are not limited thereto.

The light-emitting layers EML1b, EML2b, and EML3b may be disposed on the second hole transporting layer HTL2. A 1-2 light-emitting layer EML1b may be disposed in the first sub-pixel PX1, a 2-2 light-emitting layer EML2b may be disposed in the second sub-pixel PX2, and a 3-2 light-emitting layer EML3b may be disposed in the third sub-pixel PX3. Each of the light-emitting layers EML1b, EML2b, and EML3b may be the same as each of the light-emitting layers EML1a, EML2a, and EML3a.

A thicknesses of each light-emitting layer EML1b, EML2b, or EML3b may be different. For example, the 1-2 light-emitting layer EML1b may be formed in a thickness of 60 to 80 nm, the 2-2 light-emitting layer EML2b may be formed in a thickness of 30 to 50 nm, and the 3-2 light-emitting layer EML3b may be formed in a thickness of 10 to 30 nm, but the embodiments of the present disclosure are not limited thereto.

An electron blocking layer EBL may be disposed on each light-emitting layer EML1b, EML2b, or EML3b. The electron blocking layer EBL may be disposed integrally across the sub-pixels PX1, PX2, and PX3.

A second hole transporting layer ETL2 may be disposed on the electron blocking layer EBL. The second electron transporting layer ETL2 may be formed integrally across the sub-pixels PX1, PX2, and PX3. The second electron transporting layer ETL2 may be formed of an anthracene derivative and lithium quinolate (Liq) or formed of one or more selected from oxadiazole, triazole, phenanthroline, benzoxazole, benzthiazole, or benzimidazole (e.g., 2-[4-(9,10-Di-2-naphthalenyl-2-anthracenyl)phenyl]-1-phenyl-1H-benzimidazole), but the embodiments of the present disclosure are not limited thereto.

The second electrode 153 may be disposed on the second electron transporting layer ETL2.

Referring back to FIG. 3, the second electrode 153 may be a transparent electrode that transmits light, but the embodiments of the present disclosure are not limited thereto. For example, the second electrode 153 may include a transparent conductive material, such as indium tin oxide (ITO) or indium zinc oxide (IZO), or a metal that transmits visible light, but the embodiments of the present disclosure are not limited thereto.

A bank 154 may be disposed to expose the first electrode 151. The bank 154 may define openings (or light-emitting areas EA1, EA2, and EA3) of the sub-pixels PX1, PX2, and PX3 and may be disposed to cover an edge portion (or a periphery) of the first electrode 151. That is, the first sub-pixel PX1 may include a first light-emitting area EA1 and a first non-light-emitting area NEA1 around the first light-emitting area EA1, the second sub-pixel PX2 may include a second light-emitting area EA2 and a second non-light-emitting area NEA2 around the second light-emitting area EA2, and the third sub-pixel PX3 may include a third light-emitting area EA3 and a third non-light-emitting area NEA3 around the third light-emitting area EA3. That is, each non-light-emitting area NEA1, NEA2, or NEA3 may correspond to a boundary between adjacent sub-pixels PX1, PX2, and PX3.

The bank 154 may include a first bank 154a and a second bank 154b. In the present disclosure, the second bank 154b may also be referred to as a bank pattern, but the embodiments of the present disclosure are not limited thereto.

The first bank 154a may include a black-based material. For example, the first bank 154a may be formed of a material containing black pigment, or an organic material, such as a benzocyclobutene resin, a polyimide resin, an acrylic resin, a photosensitive polymer, etc., but the embodiments of the present disclosure are not limited thereto. When the first bank 154a is formed of a material containing black pigment or black dye, the first bank 154a may be a black bank. When the first bank 154a is formed of a material containing black pigment or black dye, it is possible to shield external light or light reflected from the outside, thereby further increasing the luminance of the display device.

The first bank 154a may include an upper surface and side surfaces. The upper surface of the first bank 154a may be flat in a horizontal direction, and the side surface of the first bank 154a may be tapered in a thickness direction.

The second bank 154b may be disposed on the side surfaces of the first bank 154a. The second bank 154b may expose a part of the upper surface of the first bank 154a. The second bank 154b may expose the entire upper surface of the first bank 154a, but the embodiments of the present disclosure are not limited thereto. The second bank 154b may not include a black-based material.

For example, the first bank 154a can suppress surface reflection of external light as described above. For example, the first bank 154a may absorb external light by including the black-based material. That is, the first bank 154a may include a resin, a black-based material in the resin, an additive for dispersing the black-based material in the resin, etc. For example, the resin may include an organic material, such as a benzocyclobutene resin, a polyimide resin, an acrylic resin, a photosensitive polymer, etc., and the additive may be, for example, a dispersant, but the embodiments of the present disclosure are not limited thereto.

The second bank 154b may include a material having a lower content of a black-based material among materials included in the first bank 154a, or may not include the black-based material at all. For example, the second bank 154b may be a transparent bank, but the embodiments of the present disclosure are not limited thereto.

Hereinafter, an optical density is introduced to distinguish the materials of the first bank 154a and the second bank 154b.

The concept of the bank 154 absorbing external light is related to the optical density. The higher the optical density (hereinafter referred to as an “OD”), which is an index of a specific material absorbing light, the higher a light absorption rate. That is, the lower the OD, the higher the light transmittance. For example, the OD may be calculated using 1 μm as a reference thickness and proportional to a thickness. Hereinafter, the OD calculated using 1 μm as a reference thickness is referred to as a “reference OD.”

Since the second bank 154b includes less or no black-based material compared to the first bank 154a, the reference OD of the first bank 154a may be higher than the reference OD of the second bank 154b.

A barrier RAS may be further disposed on the first bank 154a. As illustrated in FIG. 3, the barrier RAS may be disposed at all the boundaries NEA1, NEA2, and NEA3 between the sub-pixels PX1, PX2, and PX3, but the embodiments of the present disclosure are not limited thereto. The barrier RAS may be disposed directly on the upper surface of the first bank 154a, but the embodiments of the present disclosure are not limited thereto. The barrier RAS may serve to separate the organic layer 152 from the boundaries of adjacent sub-pixels PX1, PX2, and PX3.

A spacer 155 may be further disposed on the first bank 154a. The spacer 155 may be formed of the same material as the second bank 154b, but the embodiments of the present disclosure are not limited thereto. For example, the spacer 155 may be a transparent bank, but is not limited thereto, and may be formed of the same material as the first bank 154a. For example, the spacer 155 may be disposed on at least one of the boundaries of the first to third sub-pixels PX1, PX2, and PX3, but the embodiments of the present disclosure are not limited thereto. The second bank 154b and the spacer 155 may be formed of the same material and formed simultaneously through a halftone mask or slit, but the embodiments of the present disclosure are not limited thereto.

The organic layer 152 may be disposed on the first electrode 151, the bank 154, and the spacer 155. The second electrode 153 may be disposed on the organic layer 152.

The encapsulation part 170 may be disposed on the second electrode 153. The encapsulation part 170 may include one or more insulating layers. For example, the encapsulation part 170 may include a first encapsulation layer 171, a second encapsulation layer 172 disposed on the first encapsulation layer 171, and a third encapsulation layer 173 disposed on the second encapsulation layer 172. The encapsulation part 170 may include one or more inorganic insulation material layers and one or more organic material layers. For example, the first encapsulation layer 171 and the third encapsulation layer 173 may include an inorganic insulation material, and the second encapsulation layer 172 may include an organic material, but the embodiments of the present disclosure are not limited thereto.

The touch part 180 may be disposed on the encapsulation part 170. The touch part 180 may include the touch buffer layer 181, a first touch conductive layer, the first touch insulating layer 183, the second touch insulating layer 184, and a second touch conductive layer. In some embodiments, one or more touch organic layers may be further disposed on the second touch conductive layer, but the embodiments of the present disclosure are not limited thereto.

A bank 154 may be disposed to expose the first electrode 151. The bank 154 may define openings (or light-emitting areas EA1, EA2, and EA3) of the sub-pixels PX1, PX2, and PX3 and may be disposed to cover an edge portion (or a periphery) of the first electrode 151. That is, the first sub-pixel PX1 may include a first light-emitting area EA1 and a first non-light-emitting area NEA1 around the first light-emitting area EA1, the second sub-pixel PX2 may include a second light-emitting area EA2 and a second non-light-emitting area NEA2 around the second light-emitting area EA2, and the third sub-pixel PX3 may include a third light-emitting area EA3 and a third non-light-emitting area NEA3 around the third light-emitting area EA3. That is, each non-light-emitting area NEA1, NEA2, or NEA3 may correspond to a boundary between adjacent sub-pixels PX1, PX2, and PX3.

The bank 154 may include a first bank 154a and a second bank 154b. The first bank 154a may include a black-based material. For example, the first bank 154a may be formed of a material containing black pigment, or an organic material, such as a benzocyclobutene resin, a polyimide resin, an acrylic resin, a photosensitive polymer, etc., but the embodiments of the present disclosure are not limited thereto. When the first bank 154a is formed of a material containing black pigment or black dye, the first bank 154a may be a black bank. When the first bank 154a is formed of a material containing black pigment or black dye, it is possible to shield external light or light reflected from the outside, thereby further increasing the luminance of the display device.

The second bank 154b may be disposed between the first bank 154a and the organic layer 152. The second bank 154b may include a transparent-based material. The second bank 154b may be a transparent bank, but the embodiments of the present disclosure are not limited thereto. FIG. 3 illustrates an example in which the side surface of the first bank 154a and the side surface of the second bank 154b are aligned, but the embodiments of the present disclosure are not limited thereto. In some embodiments, the width of the first bank 154a may be greater than the width of the second bank 154b, and an end of the second bank 154b may be located farther from boundaries between the light-emitting areas EA1, EA2, and EA3 and the non-light-emitting areas NEA1, NEA2, and NEA3 than an end of the first bank 154a. That is, the second bank 154b may expose a part of an upper surface of the first bank 154a. In some other embodiments, the width of the first bank 154a may be smaller than the width of the second bank 154b, and the second bank 154b may completely cover the side surfaces of the first bank 154a.

The second bank 154b may not include a black-based material.

For example, the first bank 154a can suppress surface reflection of external light as described above. For example, the first bank 154a may absorb external light by including the black-based material. That is, the first bank 154a may include a resin, a black-based material (or black-based particles) in the resin, an additive for dispersing the black-based material in the resin, etc. For example, the resin may include an organic material, such as a benzocyclobutene resin, a polyimide resin, an acrylic resin, a photosensitive polymer, etc., and the additive may be, for example, a dispersant, but the embodiments of the present disclosure are not limited thereto.

The second bank 154b may include a material having a lower content of a black-based material among materials included in the first bank 154a, or may not include the black-based material at all. For example, the second bank 154b may be a transparent bank, but the embodiments of the present disclosure are not limited thereto.

Hereinafter, an optical density is introduced to distinguish the materials of the first bank 154a and the second bank 154b.

The concept of the bank 154 absorbing external light is related to the optical density. The higher the optical density (hereinafter referred to as an “OD”), which is an index of a specific material absorbing light, the higher a light absorption rate. That is, the lower the OD, the higher the light transmittance. For example, the OD may be calculated using 1 μm as a reference thickness and proportional to a thickness. Hereinafter, the OD calculated using 1 μm as a reference thickness is referred to as a “reference OD.”

Since the second bank 154b includes less or no black-based material compared to the first bank 154a, the reference OD of the first bank 154a may be higher than the reference OD of the second bank 154b.

The second bank 154b may further include a trench TRP. The trench TRP may completely recess the second bank 154b in the thickness direction. The trench TRP may be disposed in the non-light-emitting areas NEA1, NEA2, and NEA3. The organic layer 152 may be physically separated from the non-light-emitting areas NEA1, NEA2, and NEA3 through the trench TRP.

In some embodiments, the trench TRP may not be formed, and a barrier (not illustrated) may be further disposed on the second bank 154b. The barrier may be disposed on all boundaries NEA1, NEA2, and NEA3 between the sub-pixels PX1, PX2, and PX3, but the embodiments of the present disclosure are not limited thereto. The barrier may be disposed directly on an upper surface of the second bank 154b, but the embodiments of the present disclosure are not limited thereto. The barrier may serve to separate the organic layer 152 from the boundaries of adjacent sub-pixels PX1, PX2, and PX3.

A spacer 155 may be further disposed on the second bank 154b. The spacer 155 may be formed of the same material as the second bank 154b, but the embodiments of the present disclosure are not limited thereto. For example, the spacer 155 may be a transparent bank, but is not limited thereto, and may be formed of the same material as the first bank 154a. For example, the spacer 155 may be disposed on at least one of the boundaries of the first to third sub-pixels PX1, PX2, and PX3, but the embodiments of the present disclosure are not limited thereto. The second bank 154b and the spacer 155 may be formed of the same material and formed simultaneously through a halftone mask or slit, but the embodiments of the present disclosure are not limited thereto.

The organic layer 152 may be disposed on the first electrode 151, the bank 154, and the spacer 155. The second electrode 153 may be disposed on the organic layer 152.

The encapsulation part 170 may be disposed on the second electrode 153. The encapsulation part 170 may include one or more insulating layers. For example, the encapsulation part 170 may include a first encapsulation layer 171, a second encapsulation layer 172 disposed on the first encapsulation layer 171, and a third encapsulation layer 173 disposed on the second encapsulation layer 172. The encapsulation part 170 may include one or more inorganic insulation material layers and one or more organic material layers. For example, the first encapsulation layer 171 and the third encapsulation layer 173 may include an inorganic insulation material, and the second encapsulation layer 172 may include an organic material, but the embodiments of the present disclosure are not limited thereto.

The touch part 180 may be disposed on the encapsulation part 170. The touch part 180 may include the touch buffer layer 181, a first touch conductive layer, the first touch insulating layer 183, the second touch insulating layer 184, and a second touch conductive layer. In some embodiments, one or more touch organic layers may be further disposed on the second touch conductive layer, but the embodiments of the present disclosure are not limited thereto.

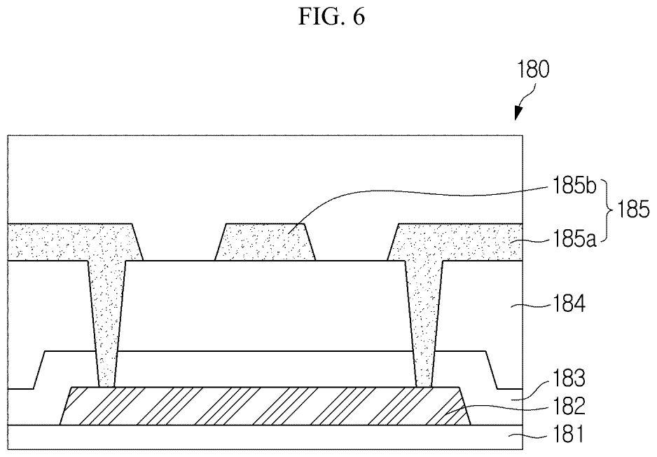

FIG. 6 is a cross-sectional view of a touch part according to FIG. 3.

Referring to FIGS. 3 and 6, the touch buffer layer 181 may be disposed on the encapsulation part 170. For example, the touch buffer layer 181 may be disposed on the third encapsulation layer 173. The touch buffer layer 181 may be formed of the same material as the buffer layer 102, but the embodiments of the present disclosure are not limited thereto.

The first touch conductive layer may be disposed on the touch buffer layer 181. The first touch conductive layer may include a bridge electrode 182. The bridge electrode 182 and a sensor electrode 185 to be described below may be disposed at each of the boundaries between adjacent sub-pixels PX1, PX2, and PX3. For example, the bridge electrode 182 and the sensor electrode 185 may be disposed in the non-light-emitting areas NEA1, NEA2, and NEA3. The bridge electrode 182 and the sensor electrode 185 may overlap the black matrix BM to be described below in the thickness direction. The black matrix BM may cover the bridge electrode 182 and the sensor electrode 185. Accordingly, the bridge electrode 182 and the sensor electrode 185 can be prevented from being visible from the outside.

The first touch insulating layer 183 and the second touch insulating layer 184 disposed on the first touch insulating layer 183 may be disposed on the first touch conductive layer. The first touch insulating layer 183 and the second touch insulating layer 184 disposed on the first touch insulating layer 183 can prevent a short circuit between the first touch conductive layer and the second touch conductive layer. The first touch insulating layer 183 may be formed of silicon oxide (SiOₓ), silicon nitride (SiNₓ), or multiple layers thereof, but the embodiments of the present disclosure are not limited thereto. The second touch insulating layer 184 may include an organic insulation material, but the embodiments of the present disclosure are not limited thereto, and the second touch insulating layer 184 may include the same material as the first touch insulating layer 183.

The second touch conductive layer may be disposed on the second touch insulating layer 184. The second touch conductive layer may include a first sensor electrode 185a and a second sensor electrode 185b. The sensor electrode 185 may include the first sensor electrode 185a extending in the first direction DR1 (see FIG. 1) and the second sensor electrode 185b extending in the second direction DR2 (see FIG. 1) different from the first direction DR1.

The bridge electrode 182 may be electrically connected to the first sensor electrode 185a through contact holes formed in the first touch insulating layer 183 and the second touch insulating layer 184. For example, the first sensor electrode 185a and the bridge electrode 182 may extend in the first direction DR1 (see FIG. 1).

The sensor electrode 185 and the bridge electrode 182 may include a metallic material. For example, the first touch conductive layer 182 may be formed of titanium (Ti), nickel (Ni), aluminum (Al), or an alloy thereof and formed of a triple layer, such as titanium (Ti)/aluminum (Al)/titanium (Ti), but the embodiments of the present disclosure are not limited thereto.

Referring back to FIG. 3, the filter insulating layer 114 may be disposed on the second touch conductive layer. The filter insulating layer 114 may be formed of an inorganic insulation material, such as silicon nitride (SiNₓ) or silicon oxide (SiOₓ), but the embodiments of the present disclosure are not limited thereto.

The black matrix BM may be disposed on the filter insulating layer 114. The black matrix BM may include a black-based material. For example, the black matrix BM may include a light-blocking material or a light-absorbing material. For example, the black matrix BM may be formed of a material including a black pigment, a black dye, etc. The black matrix BM may cover the bridge electrode 182 and the sensor electrode 185. Accordingly, the bridge electrode 182 and the sensor electrode 185 can be prevented from being visible from the outside. For example, a width of the black matrix BM may be smaller than a width of the bank 154.

For example, spacing distances between an end of the black matrix BM and boundaries between the light-emitting areas EA1, EA2, and EA3 and the non-light-emitting areas NEA1, NEA2, and NEA3 may be longer than spacing distances between an end of the bank 154 (or the first bank 154a) and the boundaries between the light-emitting areas EA1, EA2, and EA3 and the non-light-emitting areas NEA1, NEA2, and NEA3. The end of the bank 154 may be aligned with the boundaries between the light-emitting areas EA1, EA2, and EA3 and the non-light-emitting areas NEA1, NEA2, and NEA3, but the embodiments of the present disclosure are not limited thereto. In the case of the display panel 100 according to one embodiment, since the bank 154a may include a black-based material and the spacing distances between an end of the black matrix BM and boundaries between the light-emitting areas EA1, EA2, and EA3 and the non-light-emitting areas NEA1, NEA2, and NEA3 may be longer than spacing distances between an end of the bank 154a and the boundaries between the light-emitting areas EA1, EA2, and EA3 and the non-light-emitting areas NEA1, NEA2, and NEA3, light emitted from the light-emitting areas EA1, EA2, and EA3 may be emitted upward with a greater viewing angle due to a spacing space between the end of the black matrix BM and the boundaries between the light-emitting areas EA1, EA2, and EA3 and the non-light-emitting areas NEA1, NEA2, and NEA3. Accordingly, it is possible to minimize a reduction in luminance according to a viewing angle. However, when the spacing distances between the end of the black matrix BM and the boundaries between the light-emitting areas EA1, EA2, and EA3 and the non-light-emitting areas NEA1, NEA2, and NEA3 are longer than the spacing distances between the end of the bank 154a and the boundaries between the light-emitting areas EA1, EA2, and EA3 and the non-light-emitting areas NEA1, NEA2, and NEA3 and the bank 154 is formed of only a transparent material, externally incident light may be reflected by the bank 154, resulting in visible ring-shaped spots. However, in the case of the display panel 100 according to one embodiment, the externally incident light may be absorbed or blocked by the first bank 154a including a black-based material, thereby preventing the occurrence of the ring-shaped spots.

The color filters 191, 192, and 193 may be disposed on the black matrix BM. The color filters 191, 192, and 193 may be disposed on the first to third sub-pixels PX1, PX2, and PX3, respectively, and may block specific colors among light emitted from the light-emitting area EA1, EA2, and EA3 of the sub-pixels PX1, PX2, and PX3. A first color filter 191 may be provided to block light of other colors not including red (R) light. In this case, the first color filter 191 may be provided as a red color filter. A second color filter 192 may be provided to block light of other colors not including green (G) light. In this case, a second color filter 192 may be provided as a green color filter. A third color filter 193 provided in the third sub-pixel PX3 may be provided to block light of other colors not including blue (B) light. In this case, the third color filter 193 may be provided as a blue color filter. However, the embodiments of the present disclosure are not limited thereto.

For example, each color filter 191, 192, or 193 may come into direct contact with side and upper surfaces of the black matrix BM. For example, each color filter 191, 192, or 193 may be spaced apart from the boundaries of adjacent sub-pixels PX1, PX2, and PX3, but the embodiments of the present disclosure are not limited thereto, and the color filters 191, 192, and 193 may overlap each other in the thickness direction.

The planarization layer OC may be disposed on the color filters 191, 192, and 193. The planarization layer OC may serve to planarize a step formed by the color filters 191, 192, and 193. For example, the planarization layer OC may include an organic insulation material.

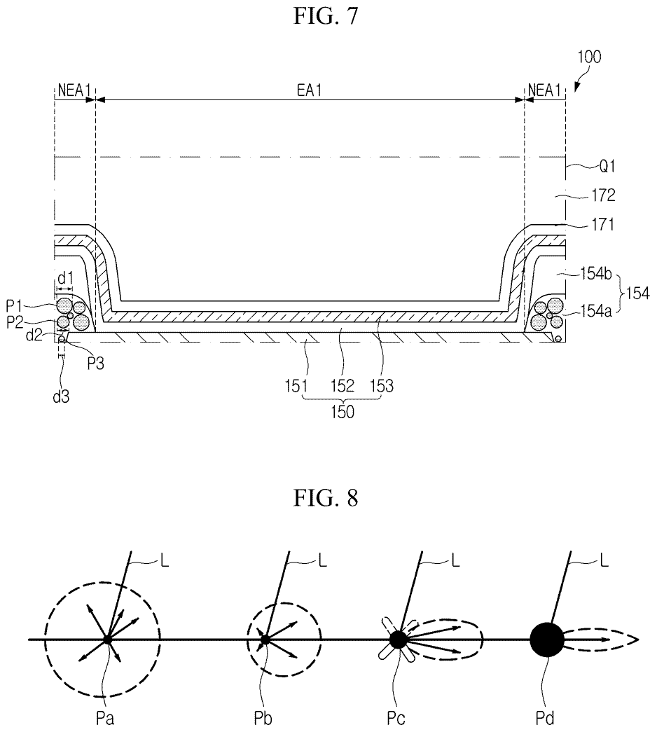

FIG. 7 is an enlarged cross-sectional view of area Q1 in FIG. 3.

Referring to FIG. 7, the first bank 154a may include a resin, and a plurality of particles P1, P2, and P3 disposed in the resin in a dispersed manner. The particles P1, P2, and P3 may be black-based particles, for example, a black pigment, a black dye, and the like, but the embodiments of the present disclosure are not limited thereto.

For example, the first bank 154a may include a plurality of particles having different diameters. For example, the plurality of particles of the first bank 154a may have three or more different diameters. In the present disclosure, an example that the plurality of particles may have three different diameters d1, d2, and d3 will be described.

The first particle P1 may have a first diameter d1, the second particle P2 may have a second diameter d2, and the third particle P3 may have a third diameter d3. In the present disclosure, the diameters d1, d2, and d3 may be diameters of the particles P1, P2, and P3, respectively, and may be represented by sizes instead of diameters. For example, the first diameter d1 may be greater than the second diameter d2, and the second diameter d2 may be greater than the third diameter d3. The diameters d1, d2, and d3 of the particles P1, P2, and P3 may be determined based on scattering rates of specific wavelengths of the particles P1, P2, and P3, respectively. The description thereof will be given below.

FIG. 8 is a view illustrating the scattering tendency of particles with different diameters with respect to light.

FIG. 8 illustrates particles having four different diameters as examples, and the particles having four different diameters may have different scattering tendencies with respect to incident light L. To show the scattering tendencies of particles Pa, Pb, Pc, and Pd with respect to the incident light L, the distribution of scattered light is marked by dotted lines and arrows.

Hereinafter, for convenience of description and to distinguish terms from those of FIG. 7, the particles Pa, Pb, Pc, and Pd will be referred to as a particle a, a particle b, a particle c, and a particle d, respectively. The incident light L may have a wavelength of about 633 nm. A diameter of the particle a may be 20 nm, a diameter of the particle b may be 150 nm, a diameter of the particle c may be 700 nm, and a diameter of the particle d may be 5000 nm. As illustrated in FIG. 8, in the case of the particle a, a scattering rate in all directions may be almost the same, in the case of the particle b, a scattering rate in one direction (e.g., a rightward direction) may be slightly higher, in the case of the particle c, for example, a scattering rate in the rightward direction may be higher than that of the particle b, and in the case of the particle d, for example, a scattering rate in the rightward direction may be higher than that of the particle c. In the present disclosure, scattering with a high scattering rate in all directions is generally referred to as Rayleigh scattering, and scattering with a high scattering rate in one direction is referred to as Mie scattering or regular reflection. For example, the particle a, the particle b, and the particle c may be generally considered as performing the Rayleigh scattering, and the particle d may be considered as performing the Mie scattering. As described below, since the particles P1, P2, and P3 of FIG. 7 need to scatter incident light so that the adjacent particles P1, P2, and P3 absorb the incident light, it is preferable to perform the Rayleigh scattering. As confirmed in FIG. 8, for the Rayleigh scattering, the diameters of the particles P1, P2, and P3 constituting the first bank 154a (see FIG. 7) is preferably about 1000 nm or less.

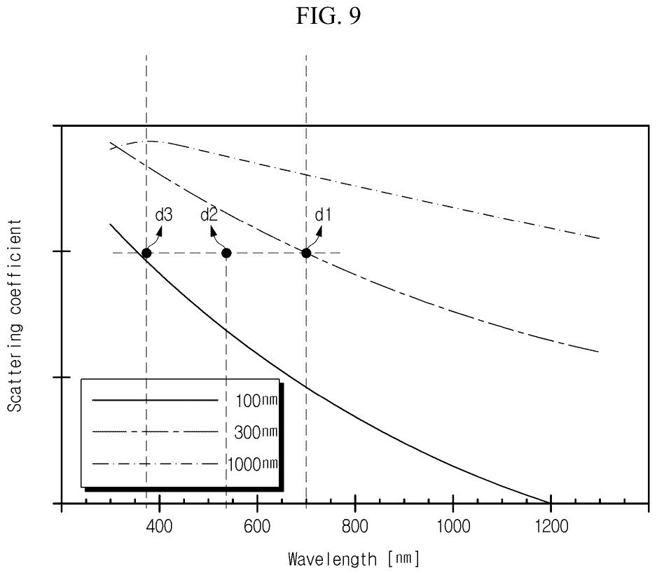

FIG. 9 is a graph illustrating a scattering rate according to the wavelength of particles with different diameters.

In FIG. 9, a horizontal axis represents a wavelength (Wavelength [μm]) of incident light, and a vertical axis represents a scattering coefficient of the incident light. FIG. 9 exemplarily illustrates scattering rates of a particle with a diameter of 100 nm, a particle with a diameter of 300 nm, and a particle with a diameter of 1000 nm according to wavelengths of the incident light. FIG. 9 is a graph for describing a method of designing the diameters d1, d2, and d3 of the particles P1, P2, and P3 of FIG. 7.

Referring to FIGS. 7 and 9, a range of the red wavelength may range from about 620 nm to about 780 nm, a range of the green wavelength may range from about 490 nm to about 570 nm, and a range of the blue wavelength may range from about 450 nm to about 490 nm. The diameters d1, d2, and d3 of the particles P1, P2, and P3 may be designed under two conditions.

A first condition is that the particles P1, P2, and P3 have the diameters d1, d2, and d3 according to a target wavelength, respectively. For example, the first particle P1 may target a red wavelength range, the second particle P2 may target a green wavelength range, and the third particle P3 may target a blue wavelength range.

The second condition is that the particles P1, P2, and P3 have the same scattering rate at the target wavelength. That is, all of a scattering rate of the first particle P1 according to the red wavelength, a scattering rate of the second particle P2 according to the green wavelength, and a scattering rate of the third particle P3 according to the blue wavelength may be the same.

As illustrated in FIG. 9, as the diameter of each particle increases, the scattering rate may be higher in the entire wavelength range, and as the wavelength of each particle decreases, the scattering rate may be higher.

Accordingly, at the same scattering rate (when a horizontal extension line is drawn along a specific scattering rate in FIG. 9), the particles P1, P2, and P3 may be designed to have the diameters d1, d2, and d3 that satisfy the target wavelength ranges (the red wavelength range, the green wavelength range, and the blue wavelength range), respectively. Accordingly, the first bank 154a may have a high scattering rate in all of the red wavelength range, the green wavelength range, and the blue wavelength range by the black-based particles P1, P2, and P3 having a plurality of diameters. For example, when the first bank 154a includes only particles targeting the green wavelength range or the blue wavelength range, the scattering rate of the particle in the red wavelength range is lower, and light of the blue wavelength range may be visible by passing through and transmitting the first bank 154a without being absorbed by the first bank 154a. However, according to the display device according to one embodiment, since the first bank 154a has a high scattering rate in all of the red wavelength range, the green wavelength range, and the blue wavelength range by the black-based particles P1, P2, and P3 having the plurality of diameters, all of light of the red wavelength, light of the green wavelength, and light of the blue wavelength may be absorbed evenly by the first bank 154a.

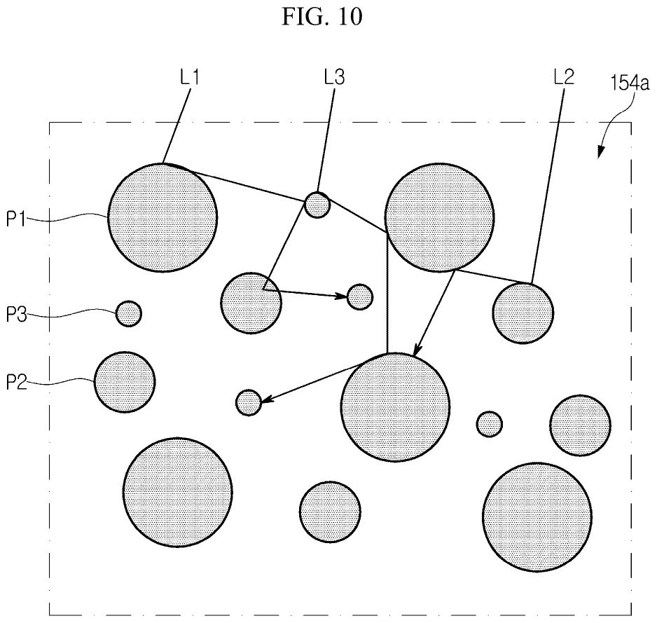

FIG. 10 is a view illustrating the scattering of a first particle, a second particle, and a third particle with respect to light of different wavelengths.

Referring to FIG. 10, light incident on the first bank 154a may include red light L1, green light L2, and blue light L3, and each light L1, L2, or L3 satisfies the red wavelength range, the green wavelength range, and the blue wavelength range described above in FIG. 9. As illustrated in FIG. 10, the particles P1, P2, and P3 have similar or the same scattering rate with respect to the light L1, L2, and L3 of different target wavelength ranges, and the light L1, L2, and L3 scattered by the particles P1, P2, and P3 may be multi-scattered and absorbed by the particles P1, P2, and P3 formed of a black-based material.

In addition, according to the display device according to one embodiment, since the first bank 154a includes the particles P1, P2, and P3 having different diameters, as illustrated in FIGS. 7 and 10, more particles P1, P2, and P3 may be disposed in the first bank 154a. For example, when the first particles P1 having the greatest diameter are disposed, empty spaces may be formed between the first particles P1, and the empty spaces between the first particles P1 may be filled with the second particles P2 having the next greatest diameter. Furthermore, empty spaces may be formed between the second particles P2, and the empty spaces between the second particles P2 may be filled with the third particles P3 having the smallest diameter.

Hereinafter, a display device according to other embodiments will be described. In the following embodiments, the detailed description of the reference numerals or components described in FIGS. 1 to 10 will be omitted, or the overlapping descriptions thereof will be omitted.

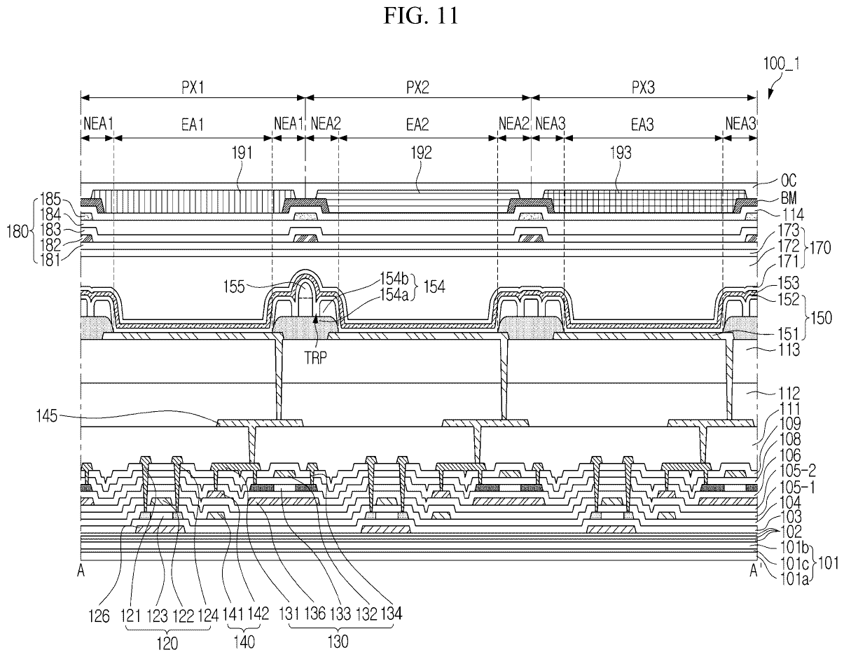

FIG. 11 is a cross-sectional view of a display device according to another embodiment.

Referring to FIG. 11, a display panel 100_1 of the display device according to the present embodiment differs from the display panel 100 according to FIG. 3 in that it may further include a third protective layer 113 on the second protective layer 112.

More specifically, a display panel 100_1 according to the present embodiment may further include the third protective layer 113 between the second protective layer 112 and the first electrode 151. A material of the third protective layer 113 may include at least one of materials exemplified as the material of the second protective layer 112, but the embodiments of the present disclosure are not limited thereto.

Since the remaining parts have been described above in FIG. 3, the detailed descriptions thereof will be omitted.

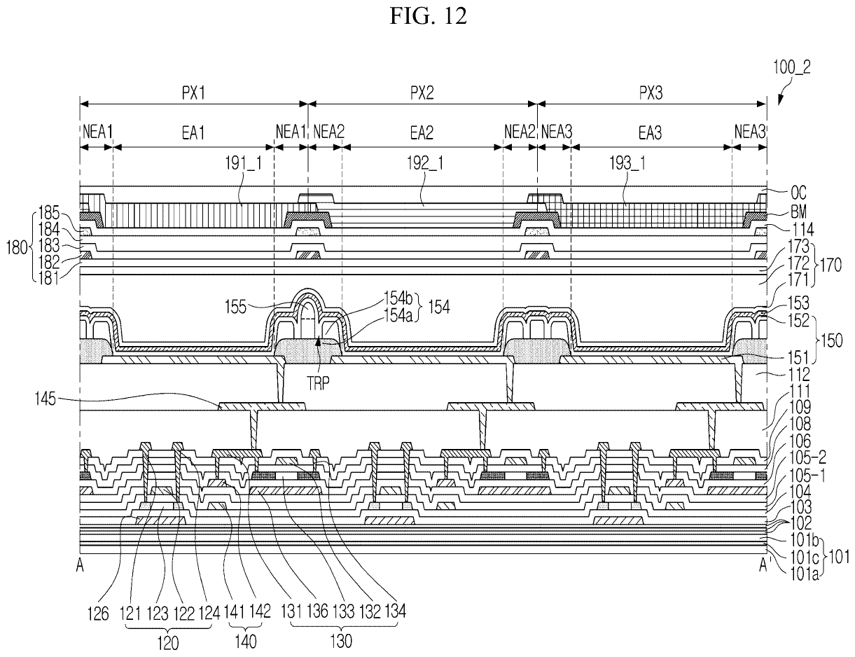

FIG. 12 is a cross-sectional view of a display device according to still another embodiment.

Referring to FIG. 12, color filters 191_1, 192_1, and 193_1 of a display panel 100_2 of the display device according to the present embodiment differ from the display panel 100 according to FIG. 3 in that they may overlap each other in the non-light-emitting areas NEA1, NEA2, and NEA3.

FIG. 12 illustrates that a second color filter 192_1 is located at the top, a first color filter 191_1 is located under the second color filter 192_1, and lastly, a third color filter 193_1 is located at the bottom in each non-light-emitting area NEA1, NEA2, or NEA3, but the stacking order of the color filter 191_1, 192_1, and 193_1 in the non-light-emitting areas NEA1, NEA2, and NEA3 may vary according to a process order.

Since the remaining parts have been described above in FIG. 3, the detailed descriptions thereof will be omitted.

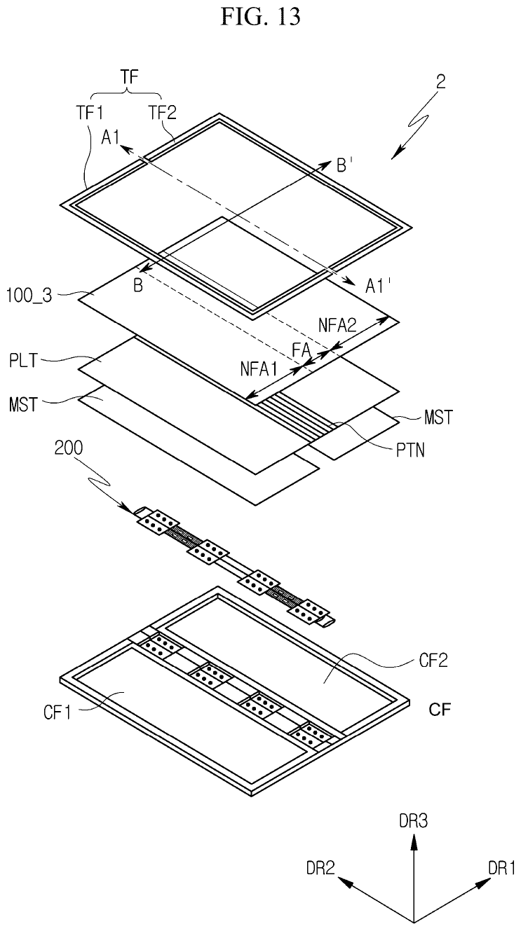

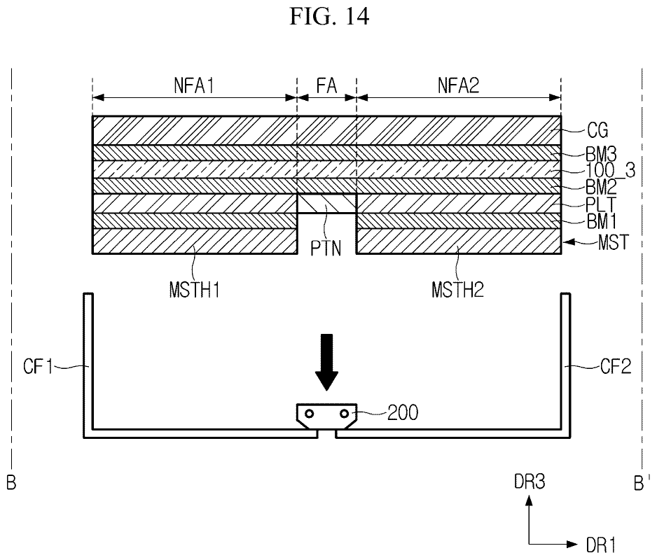

FIG. 13 is a perspective view of a display device according to yet another embodiment. FIG. 14 is a cross-sectional view along line B-B′ in FIG. 13.

Referring to FIGS. 13 and 14, a display device 2 according to the present embodiment differs from the display device 1 according to FIG. 1 in that it is a foldable display device.

In the present disclosure, a folding axis A1-A1′ along which the display device 2 is folded may be the same as the second direction DR2.

A top frame TF is disposed at the top of the display device 2. With respect to the folding axis A1-A1′, the top frame TF includes a first top frame TF1 disposed at one side and a second top frame TF2 disposed at the other side. The top frame TF may be disposed to cover an edge of the display panel 100_3. The top frame TF may protect the display panel 100_3 from an external impact. The top frame TF may form a bezel of the display device 2.

A cover layer CG may be disposed under the top frame TF. The cover layer CG may be disposed above the display panel 100_3.

The cover layer CG may be disposed above the display panel 100_3 to protect members disposed under the cover layer CG from the outside.

A panel assembly is disposed under the cover layer CG. The panel assembly includes the display panel 100_3 and a plate PLT. The display panel 100_3 may be substantially the same as one of the display panels 100, 100_1, and 100_2.

The plate PLT may be disposed under the display panel 100_3 and may include various plates for supporting the display panel 100_3. For example, one or more plates may include a back plate for supporting the display panel 100_3, a top plate disposed under the back plate and formed of a stainless steel (SUS) material, a bottom plate disposed under the top plate, having a pattern formed on a folding portion, and formed of a SUS material, a heat-dissipation sheet that performs a heat-dissipation function, a middle plate for covering a non-planarized flat surface caused by various components of a hinge assembly, etc.

A slit pattern PTN may be formed in the plate PLT. The slit pattern PTN may be formed at a location corresponding to a folding area FA of the display panel 100_3. The slit pattern PTN may be a slit-shaped etched portion formed in the plate PLT. For example, the plate PLT may be formed of a metal, such as a SUS material, but the strong nature of the metal may cause problems in folding or unfolding the plate PLT. The slit pattern PTN may supplement the flexibility of the plate PLT.

A middle plate MST is disposed under the panel assembly. The middle plate MST supports components disposed upward. In addition, a hinge assembly 200 and a cover frame CF are disposed downward from the middle plate MST, and their upper surfaces may be uneven. The middle plate MST may flatten a non-planarized lower surface. The middle plate MST may be formed of a material, such as plastic, polyimide, or metal, to increase the rigidity of the display device 2. For example, the middle plate MST may include aluminum or SUS, but is not limited thereto.

The middle plate MST may include a first middle plate portion MSTH1 disposed in a first unfolding area NFA1, and a second middle plate portion MSTH2 disposed in a second unfolding area NFA2.

The hinge assembly 200 is disposed under the panel assembly. The hinge assembly 200 is disposed under the folding area FA. The hinge assembly 200 may have a shape extending along the folding axis A1. The hinge assembly 200 may perform a folding motion in which one side and the other side rotate about the folding axis A1.

The cover frame CF is disposed under the hinge assembly 200. An accommodation groove in which a part of the hinge assembly 200 may be seated may be formed in an upper surface of the cover frame CF. With respect to the folding axis A1, the cover frame CF includes a first cover frame CF1 disposed at one side and a second cover frame CF2 disposed at the other side. The cover frame CF may be a housing for defining the side and rear surfaces of the display device 2. The cover frame CF may protect the display device 2 from an external impact. The cover frame CF may be coupled to the hinge assembly 200. Folding and unfolding of the display device 2 may be implemented according to the rotation of the cover frames CF1 and CF2.

Coupling members BM1, BM2, and BM3 for coupling the adjacent members MST, PLT, PNL, and CG may be further disposed between the adjacent members. In each of the unfolding areas NFA1 and NFA2, a first coupling member BM1 may couple the middle plate portions MSTH1 and MSTH2 to the plate PLT disposed above the middle plate portions MSTH1 and MSTH2, a second coupling member BM2 may couple the plates PLT and PTN to the display panel 100_3 disposed above the plates PLT and PTN, and a third coupling member BM3 may couple the display panel 100_3 to the cover layer CG.

The plate PLT and the middle plate MST that are coupled may be seated on the cover frames CF1 and CF2. The display device 2 may perform folding and unfolding operations by the hinge assembly 200 disposed on the cover frames CF1 and CF2.

Since the display panel 100_3 has been described above, the detailed descriptions thereof will be omitted below.

A display device according to various embodiments of the present disclosure may be described as follows.

According to embodiments of the present disclosure, there is provided a display device including a substrate, a display area including a plurality of sub-pixels, a non-display area outside the display area, a first electrode disposed in each of the sub-pixels on the substrate in the display area, and a bank disposed on the first electrode of the display area and located at a boundary between adjacent sub-pixels and overlapping a periphery of an upper surface of the first electrode, in which the bank includes a plurality of black-based particles having different diameters.

In the display device according to the embodiments of the present disclosure, scattering rates of the plurality of black-based particles may increase as a wavelength of incident light decreases.

In the display device according to the embodiments of the present disclosure, the plurality of black-based particles may have a diameter greater than 0 nm and less than or equal to 1000 nm.

In the display device according to the embodiments of the present disclosure, the plurality of black-based particles may include a first particle having a first diameter, a second particle having a second diameter smaller than the first diameter, and a third particle having a third diameter smaller than the second diameter.

In the display device according to the embodiments of the present disclosure, a scattering rate of the first particle with respect to red light, a scattering rate of the second particle with respect to green light, and a scattering rate of the third particle with respect to blue light may be the same.

In the display device according to the embodiments of the present disclosure, the black-based particles may include a black pigment or a black dye.

In the display device according to the embodiments of the present disclosure, the plurality of sub-pixels may include a first sub-pixel, a second sub-pixel, and a third sub-pixel and further include an organic layer on the bank, in which the organic layer may be disposed across the first sub-pixel, the second sub-pixel, and the third sub-pixel.

In the display device according to the embodiments of the present disclosure, the organic layer may include a first light-emitting layer on the first sub-pixel, a second light-emitting layer on the second sub-pixel, and a third light-emitting layer on the third sub-pixel.

In the display device according to the embodiments of the present disclosure, each of the first light-emitting layer, the second light-emitting layer, and the third light-emitting layer may be stacked in two or more layers.

The display device according to the embodiments of the present disclosure may further includes a second electrode on the organic layer, a color filter on the second electrode, and a black matrix located at a boundary between the adjacent sub-pixels between the second electrode and the color filter, in which a width of the black matrix may be smaller than a width of the bank.

In the display device according to the embodiments of the present disclosure, an end of the black matrix may be closer to the boundary between the sub-pixels than an end of the bank.

The display device according to the embodiments of the present disclosure may further include a touch part between the second electrode and the color filter, in which the touch part may include a bridge electrode, and a sensor electrode on the bridge electrode, and the black matrix may overlap the bridge electrode and the sensor electrode.

The display device according to the embodiments of the present disclosure may further include a first transistor between the substrate and the first electrode, and a second transistor between the first transistor and the first electrode, in which a semiconductor layer of the first transistor may include polysilicon, and a semiconductor layer of the second transistor may include oxide.

According to embodiments of the present disclosure, there is provided a display device including a substrate, a display area, a non-display area outside the display area, a first electrode on the substrate in the display area, and a bank disposed on the first electrode in the display area and overlapping a periphery of an upper surface of the first electrode, in which the bank includes a plurality of black-based particles, and the plurality of black-based particles may have a plurality of diameters to generate a scattering rate with respect to red light, a scattering rate with respect to green light, and a scattering rate with respect to blue light, and in which the scattering rate with respect to the red light, the scattering rate with respect to the green light, and the scattering rate with respect to the blue light are same.

In the display device according to the embodiments of the present disclosure, scattering rates of the plurality of black-based particles may increase as a wavelength of incident light decreases.

In the display device according to the embodiments of the present disclosure, the plurality of black-based particles may have a diameter greater than 0 nm and less than or equal to 1000 nm.

In the display device according to the embodiments of the present disclosure, the plurality of black-based particles may have at least three diameters.

In the display device according to the embodiments of the present disclosure, the black-based particles may include a black pigment or a black dye.

In the display device according to the embodiments, it is possible to efficiently increase the optical density of the bank by including black-based particles having a plurality of sizes in the bank to arrange more particles in the same space.

In the display device according to the embodiments, it is possible to increase the scattering rate in all of the red wavelength, the green wavelength, and the blue wavelength by including black-based particles having a plurality of sizes (or diameters) in the bank.

In the display device according to the embodiments, it is possible to improve external light reflection (or surface reflection) by increasing the scattering rate in all of the red wavelength, the green wavelength, and the blue wavelength.

According to the embodiments of the present disclosure, the surface reflection of external light can be improved to provide low-reflection display device, thereby achieving low power.

According to the embodiments of the present disclosure, by omitting the polarizing unit, the display device can have improved flexibility and can be applied to a foldable product in which a display area is folded.

However, effects obtainable from the present disclosure are not limited to the above-described effects, and other effects that are not mentioned will be able to be clearly understood by those skilled in the art to which the present disclosure pertains based on the following description.

Although the embodiments of the present disclosure have been described above with reference to the accompanying drawings, those skilled in the art to which the present disclosure pertains will be able to understand that the above-described technical configuration of the present disclosure can be carried out in other specific forms without changing the technical spirit or essential features thereof. Accordingly, it should be understood that the above-described embodiments are illustrative and not restrictive in all respects. In addition, the scope of the present disclosure is described by the claims to be described below rather than the detailed description. In addition, the meaning and scope of the claims and all changed or modified forms derived from the equivalent concept should be construed as being included in the scope of the present disclosure.

What is claimed is:

1. A display device, comprising:
a substrate;
a display area including a plurality of sub-pixels, and a non-display area outside the display area;
a first electrode disposed in each of the plurality of sub-pixels on the substrate in the display area; and
a bank disposed on the first electrode of the display area and located at a boundary between adjacent sub-pixels and overlapping a periphery of an upper surface of the first electrode,
wherein the bank includes a plurality of black-based particles having different diameters.

2. The display device of claim 1, wherein scattering rates of the plurality of black-based particles increase as a wavelength of incident light decreases.

3. The display device of claim 1, wherein the plurality of black-based particles have a diameter greater than 0 nm and less than or equal to 1000 nm.

4. The display device of claim 1, wherein the plurality of black-based particles include a first particle having a first diameter, a second particle having a second diameter smaller than the first diameter, and a third particle having a third diameter smaller than the second diameter.

5. The display device of claim 4, wherein a scattering rate of the first particle with respect to red light, a scattering rate of the second particle with respect to green light, and a scattering rate of the third particle with respect to blue light are same.

6. The display device of claim 1, wherein the black-based particles include a black pigment or a black dye.

7. The display device of claim 1, wherein the plurality of sub-pixels include a first sub-pixel, a second sub-pixel, and a third sub-pixel and further include an organic layer on the bank, wherein the organic layer is disposed across the first sub-pixel, the second sub-pixel, and the third sub-pixel.

8. The display device of claim 7, wherein the organic layer includes a first light-emitting layer on the first sub-pixel, a second light-emitting layer on the second sub-pixel, and a third light-emitting layer on the third sub-pixel.

9. The display device of claim 8, wherein, each of the first light-emitting layer, the second light-emitting layer, and the third light-emitting layer is stacked in two or more layers.

10. The display device of claim 7, further comprising: a second electrode on the organic layer; a color filter on the second electrode; and a black matrix located at a boundary between the adjacent sub-pixels between the second electrode and the color filter, wherein a width of the black matrix is smaller than a width of the bank.

11. The display device of claim 10, wherein an end of the black matrix is closer to a boundary between the adjacent sub-pixels than an end of the bank.

12. The display device of claim 10, further comprising a touch part between the second electrode and the color filter, wherein the touch part includes a bridge electrode, and a sensor electrode on the bridge electrode, and the black matrix overlaps the bridge electrode and the sensor electrode.

13. The display device of claim 1, further comprising: a first transistor between the substrate and the first electrode; and a second transistor between the first transistor and the first electrode, wherein a semiconductor layer of the first transistor includes polysilicon, and a semiconductor layer of the second transistor includes oxide.

14. A display device, comprising:
a substrate;
a display area, and a non-display area outside the display area;
a first electrode on the substrate in the display area; and
a bank disposed on the first electrode of the display area and located at a boundary between adjacent sub-pixels and overlapping a periphery of an upper surface of the first electrode,
wherein the bank includes a plurality of black-based particles,
wherein the plurality of black-based particles have a plurality of diameters to generate a scattering rate with respect to red light, a scattering rate with respect to green light, and a scattering rate with respect to blue light, and
wherein the scattering rate with respect to the red light, the scattering rate with respect to the green light, and the scattering rate with respect to the blue light are same.

15. The display device of claim 14, wherein scattering rates of the plurality of black-based particles increase as a wavelength of incident light decreases.

16. The display device of claim 4, wherein the plurality of black-based particles have a diameter greater than 0 nm and less than or equal to 1000 nm.

17. The display device of claim 14, wherein the plurality of black-based particles have at least three diameters.

18. The display device of claim 14, wherein the black-based particles include a black pigment or a black dye.
